(19) United States
(12) Patent Application Publication
(10) Pub. No.: US 2026/0233259 A1
(43) Pub. Date: Aug. 13, 2026

(54) CLEANING TOOL FOR SUBSTRATE SUPPORT MEMBER, SUBSTRATE PROCESSING APPARATUS AND METHOD FOR CLEANING SUBSTRATE SUPPORT MEMBER

(71) Applicant: Tokyo Electron Limited, Tokyo (JP)

(72) Inventors: Tomoyuki HASHIMOTO, Kumamoto (JP); Yoshifumi AMANO, Yamanashi (JP); Kazuhiro AIURA, Kumamoto (JP); Takafumi KINOSHITA, Kumamoto (JP); Yuki ITO, Kumamoto (JP)

(21) Appl. No.: 19/535,408

(22) Filed: Feb. 10, 2026

(30) Foreign Application Priority Data
Feb. 12, 2025 (JP) 2025-020767

(51) Int. Cl. B08B 3/04

(52) U.S. Cl. CPC B08B 3/041

(57) ABSTRACT

A cleaning tool includes a lower surface including a central region including a center portion and an outer region extending outward from the central region. A cleaning liquid is supplied to the lower surface in a state where the lower surface is supported by at least one of the plurality of substrate support members, thereby cleaning the plurality of substrate support members. In a state where the lower surface is supported by at least one of the plurality of substrate support members, the outer region includes at least one protrusion at which at least one of the plurality of substrate support members are in contact with the lower surface, and at least one recess at which the other ones of the plurality of substrate support members are spaced apart from the lower surface.

### CROSS REFERENCES TO RELATED APPLICATIONS

This application is based on and claims priority from Japanese Patent Application No. 2025-020767, filed on February 12, 2025, with the Japan Patent Office, the disclosure of which is incorporated herein in its entirety by reference.

### TECHNICAL FIELD

The present disclosure relates to a cleaning tool for a substrate support member, a substrate processing apparatus, and a method for cleaning the substrate support member.

### BACKGROUND

Japanese Patent Laid-Open Publication No. 2022-063043 discloses a substrate cleaning method in which a substrate supported by a support member is rotated, and a cleaning liquid is supplied toward the back surface of the substrate, thereby shaking off the cleaning liquid toward the outer periphery of the substrate to clean the back surface of the substrate and a peripheral member surrounding the outer periphery of the substrate.

### SUMMARY

An example of a cleaning tool for a substrate support member is a disc-shaped cleaning tool for cleaning a plurality of substrate support members, and the cleaning tool includes a lower surface including a central region including a center portion and an annular outer region extending outward from the central region, in which a cleaning liquid is supplied to the lower surface of the cleaning tool in a state where the lower surface of the cleaning tool is supported by at least one of the plurality of substrate support members, thereby cleaning the plurality of substrate support members. In a state where the lower surface of the cleaning tool is supported by at least one of the plurality of substrate support members, the outer region includes at least one protrusion at which at least one of the plurality of substrate support members is in contact with the lower surface of the cleaning tool, and at least one recess at which the other ones of the plurality of substrate support members are spaced apart from the lower surface of the cleaning tool.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating an example of a substrate cleaning apparatus.

FIG. 2 is a perspective view illustrating an example of a cleaning tool viewed from below.

FIG. 3 is a front view illustrating a lower surface of the cleaning tool of FIG. 2.

FIG. 4 is a cross-sectional view partially illustrating the vicinity of the annular member of FIG. 1, taken along line IV-IV of FIG. 3.

FIG. 5 is a cross-sectional view partially illustrating the vicinity of the annular member of FIG. 1, taken along line V-V of FIG. 3.

FIG. 6 is a block diagram illustrating an example of a main portion of the substrate cleaning apparatus.

FIG. 7 is a schematic diagram illustrating an example of a hardware configuration of a controller.

FIGS. 8A and 8B are diagrams illustrating an example of a cleaning process of a plurality of support pins by the cleaning tool.

FIGS. 9A and 9B are diagrams illustrating a subsequent process of FIGS. 8A and 8B.

FIGS. 10A and 10B are diagrams illustrating a subsequent process of FIGS. 9A and 9B.

FIGS. 11A and 11B are diagram illustrating a subsequent process of FIGS. 10A and 10B.

FIG. 12 is a flowchart illustrating an example of the cleaning process of the plurality of support pins by the cleaning tool.

FIG. 13 is a perspective view illustrating another example of the cleaning tool viewed from below.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In the following description, the same reference numerals are given for the same element or elements having the same function, and redundant descriptions are omitted. It is to be noted that, throughout the description, upper, lower, right, and left directions in the drawings are based on directions of the symbols in the drawings.

### Configuration of substrate cleaning apparatus

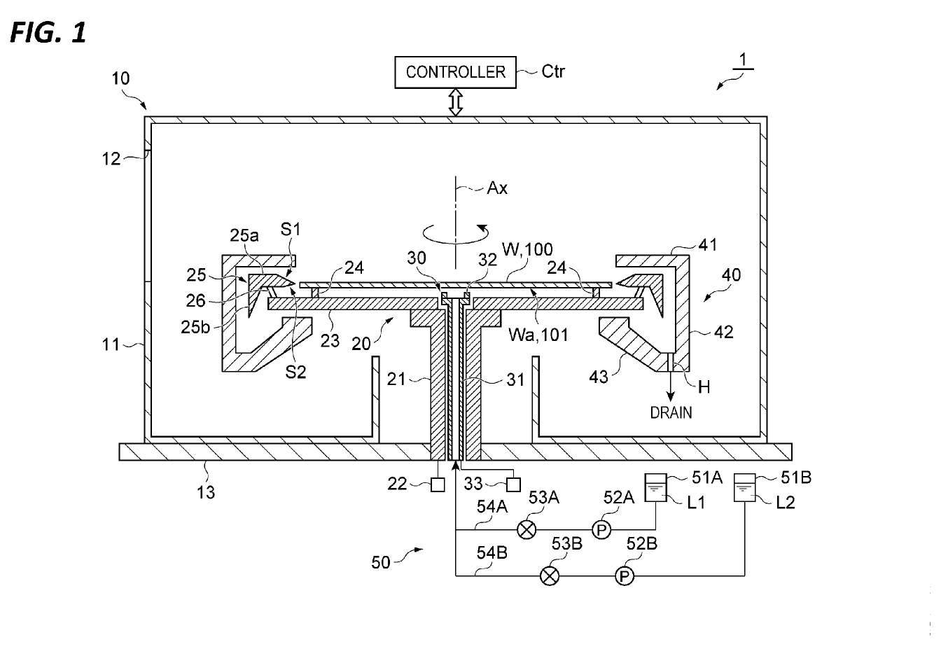

First, the configuration of an example of a substrate cleaning apparatus 1 will be described with reference to FIGS. 1 to 7. The substrate cleaning apparatus 1 is configured to clean a lower surface Wa of a substrate W with a cleaning liquid L2 to be described below, as illustrated in FIG. 1. Using the cleaning tool 100, the substrate cleaning apparatus 1 is configured to clean support pins 24 (substrate support members), an annular member 25, and a cover 40, which will be described below, with the cleaning liquid L2.

The substrate W may have a disc plate shape or a non-circular plate shape such as a polygonal plate. The substrate W may include a cutout portion formed in a portion of the substrate W. The cutout portion may be, for example, a notch (e.g., a U-shaped groove or a V-shaped groove), or a straight portion (e.g., so-called an orientation flat) extending in a straight line. The substrate W may be, for example, a semiconductor substrate (e.g., a silicon wafer), a glass substrate, a mask substrate, a flat panel display (FPD) substrate, and various other substrates. The diameter of the substrate W may be, for example, about 200 mm to 450 mm.

The cleaning tool 100 may have the same shape as the substrate W. The size of the cleaning tool 100 may be approximately the same as the size of the substrate W. Hereinafter, an example where the cleaning tool 100 has a disc plate shape will be described.

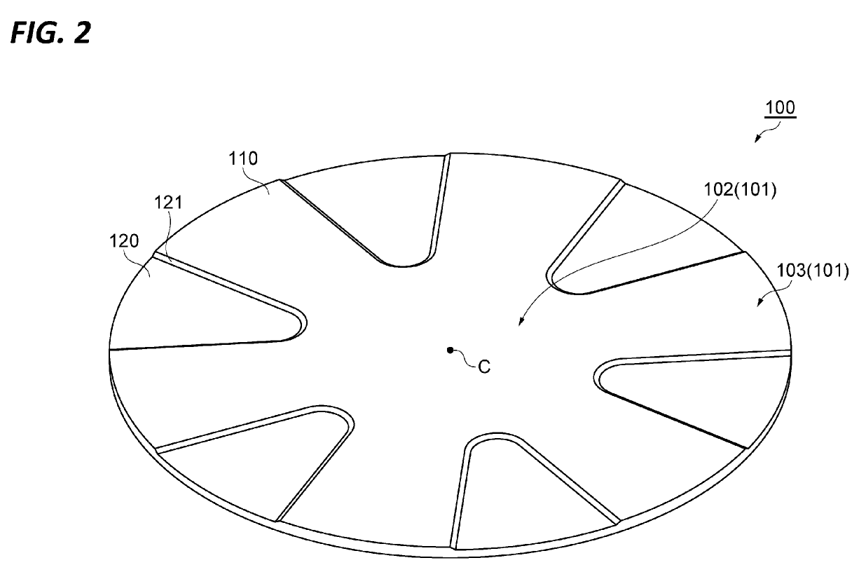

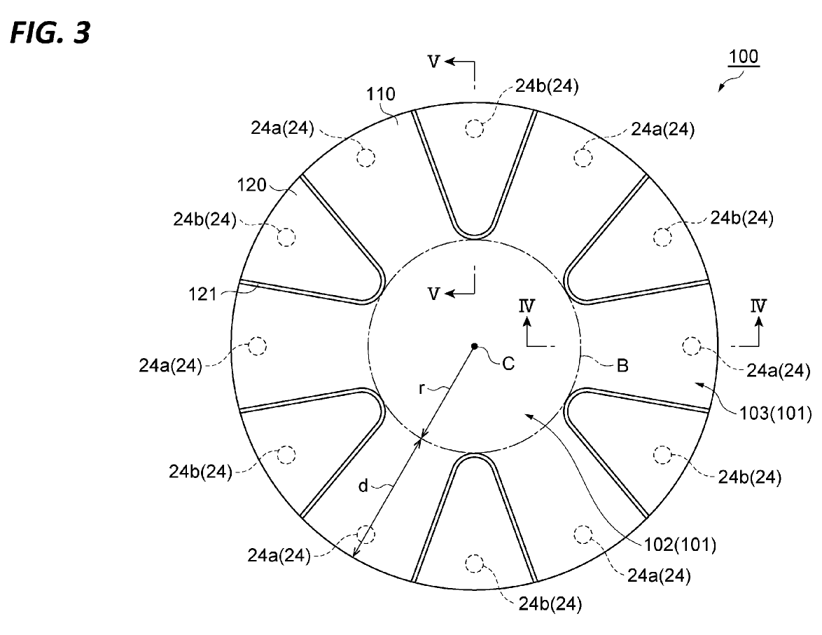

The cleaning tool 100 includes a lower surface 101 having a concave-convex shape, as illustrated in FIGS. 2 and 3. In this description, the lower surface 101 of the cleaning tool 100 refers to the surface of the concave-convex shape. The lower surface 101 includes a central region 102 including the center C (e.g., a center portion) of the cleaning tool 100, and an annular outer region 103 extending outward from the central region 102.

The central region 102 may be a circular region having a radius r from the center C, as illustrated in FIG. 3. In FIG. 3, the central region 102 is in a circular shape as indicated by a dashed-dot line.

The outer region 103 includes at least one protrusion 110 and at least one recess 120 formed therein. The positions of the protrusions 110 and the recesses 120 in the outer region 103, or the shape of the protrusions 110 and the recesses 120 are not particularly limited.

A plurality of protrusions 110 and a plurality of recesses 120 may be formed in the outer region 103. When the plurality of protrusions 110 and the plurality of recesses 120 are formed in the outer region 103, the protrusions and recesses may be arranged along a circumferential direction of the cleaning tool 100 (e.g., the outer region 103) (in this description, simply referred to as a “circumferential direction" in some cases). The plurality of protrusions 110 and the plurality of recesses 120 may be alternately disposed in the circumferential direction.

As illustrated in FIGS. 2 and 3, six protrusions 110 and six recesses 120 may be formed in the outer region 103. In this case, the protrusions 110 and the recesses 120 may be alternately disposed at approximately 30° intervals along the circumferential direction.

As illustrated in FIGS. 2 and 3, the surface of the protrusions 110 may be substantially co-planar with the surface of the central region 102. Alternatively, the surface of the protrusions 110 may protrude relative to the surface of the central region 102 or may be recessed relative to the surface of the central region 102. The protrusions 110 may extend in a radial direction of the cleaning tool 100 (e.g., the outer region 103) (in this description, simply referred to as a "radial direction" in some cases). In other words, the protrusions 110 may extend in the radial direction from the center C side toward an outer peripheral edge of the lower surface 101.

The surface of the recesses 120 is recessed deeper than the surface of the protrusions 110. As in the protrusions 110, the recesses 120 may extend in the radial direction of the cleaning tool 100 (the outer region 103). In the examples of FIGS. 2 and 3, the recesses 120 extend from a boundary (B) between the central region 102 and the outer region 103 to the outer peripheral edge of the lower surface 101 in the radial direction. When the plurality of recesses 120 are formed in the outer region 103, the plurality of recesses 120 may extend radially.

The width (e.g., the length in the circumferential direction) of the recesses 120 may gradually widen from the center C side toward the outer peripheral edge of the lower surface 101. The recesses 120 may have a fan shape or a triangular shape.

The length d of the recesses 120 in the radial direction (see, e.g., FIG. 3) may be longer than a straight-line distance from the center C to the peripheral edge portion 121 of the recesses 120 in the radial direction. As illustrated in FIG. 3, when the peripheral edge portion 121 of the recesses 120 extends from the boundary B, the length d may be longer than the radius r.

As illustrated in FIG. 2, the peripheral edge portion 121 of the recesses 120 may be inclined so as to widen outward the recesses 120. That is, the peripheral edge portion 121 may form an inclined surface that gradually increases in height outward the recesses 120.

Referring back to FIG. 1, the substrate cleaning apparatus 1 includes a housing 10, a rotation unit 20 (e.g., a support unit), a lift unit 30, the cover 40, a supply unit 50, and a controller Ctr (e.g., a control unit). The housing 10 mainly accommodates therein the rotation unit 20, the lift unit 30, and the cover 40. A load/unload port 12 is formed on a sidewall 11 of the housing 10. The substrate W is loaded into the housing 10 through the load/unload port 12 by a transport mechanism (e.g., a robot arm) (not illustrated), and is also unloaded from the housing 10 to the outside.

The rotation unit 20 includes a rotating shaft 21, a drive mechanism 22, a support plate 23, a plurality of support pins 24, and the annular member 25. The rotating shaft 21 is a hollow tubular member extending in a vertical direction. The rotating shaft 21 is attached to a bottom wall 13 of the housing 10 to be rotatable around a central axis Ax.

The drive mechanism 22 is connected to the rotating shaft 21. The drive mechanism 22 is configured to be operated to rotate the rotating shaft 21 based on an operation signal from the controller Ctr. The drive mechanism 22 may be a power source such as an electric motor.

The support plate 23 is, for example, a flat plate in an annular shape and extends along a horizontal direction. That is, a through hole is formed in a center portion of the support plate 23. The inner peripheral portion of the support plate 23 is connected to a tip portion of the rotating shaft 21. Therefore, the support plate 23 is configured to be rotated around the central axis Ax of the rotating shaft 21 in accordance with the rotation of the rotating shaft 21.

The plurality of support pins 24 are installed on the support plate 23 to protrude upward from an upper surface of the support plate 23. The plurality of support pins 24 are configured to support the substrate W approximately horizontally by the tips thereof contacting the lower surface W of the substrate W. The plurality of support pins 24 are configured to support the cleaning tool 100 approximately horizontally by the tips thereof contacting the lower surface 101 of the cleaning tool 100. That is, the rotation unit 20 is configured to support the substrate W or the cleaning tool 100 from below, and rotate the substrate W or the cleaning tool 100.

The plurality of support pins 24 may have, for example, a cylindrical shape or a conical shape. The plurality of support pins 24 may be disposed at approximately equal intervals in the vicinity of the outer peripheral portion of the support plate 23 to form a circular shape as a whole when viewed from above. For example, when the plurality of support pins 24 include twelve support pins 24, the plurality of support pins 24 may be disposed at approximately 30° intervals.

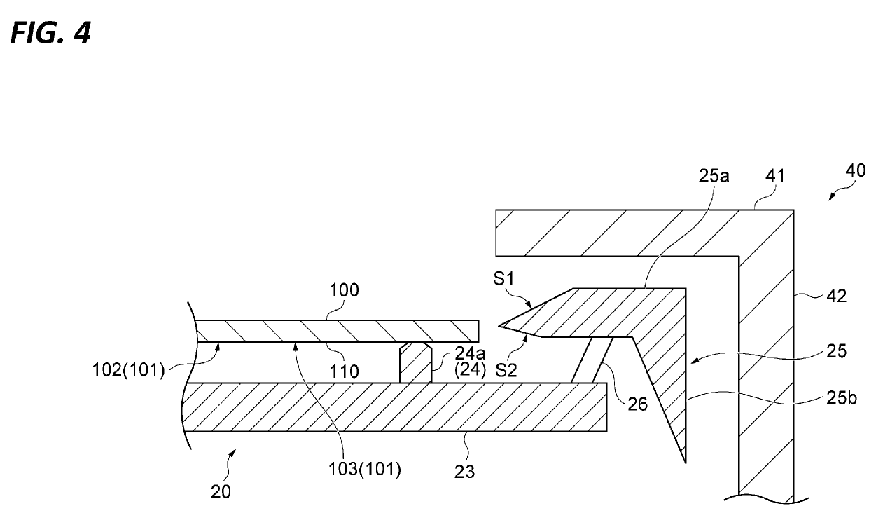

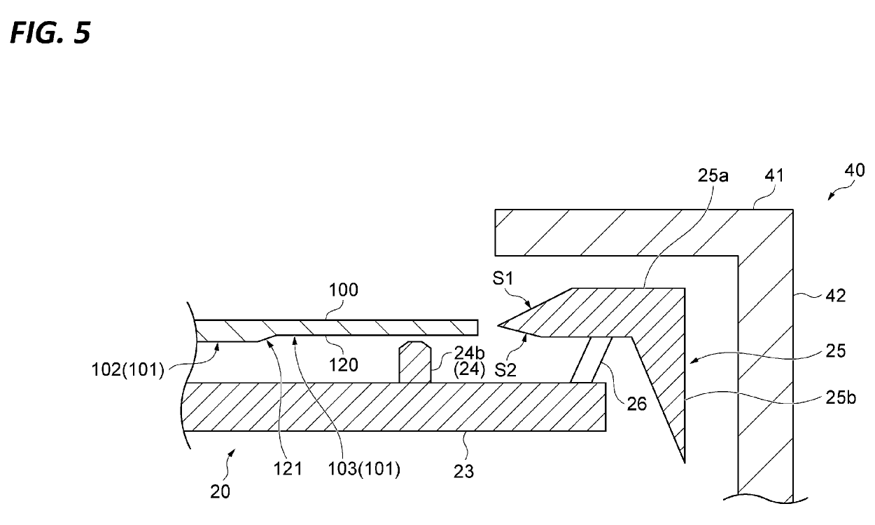

When the lower surface 101 of the cleaning tool 100 is supported by the rotation unit 20, some support pins 24a of the plurality of support pins 24 are in contact with the lower surface 101 (the protrusions 110), and the other support pins 24a of the plurality of support pins 24 are spaced apart from the lower surface 101 (the recesses 120). When the total number of the plurality of support pins 24, the plurality of protrusions 110, and the plurality of recesses 120 are the same, in a state where the lower surface 101 of the cleaning tool 100 is supported by the rotation unit 20, the plurality of support pins 24 may be disposed as illustrated in FIG. 3. That is, some support pins 24a of the plurality of support pins 24 may be positioned to correspond to the protrusions 110 respectively, as illustrated in FIGS. 3 and 4, and may also be in contact with the surface of the corresponding protrusions 110. As illustrated in FIGS. 3 and 5, the other support pins 24b of the plurality of support pins 24 may be positioned to correspond to the recesses 120 respectively, and may be spaced apart from the surface of the corresponding recesses 120.

Referring back to FIG. 1, the annular member 25 has an annular shape and is disposed to surround the outer peripheral portion of the support plate 23. The annular member 25 is connected to the outer peripheral portion of the support plate 23 by a plurality of connection members 26. Therefore, the annular member 25 is configured to be rotated around the central axis Ax of the rotating shaft 21 in accordance with the rotation of the rotating shaft 21.

The annular member 25 may include an upper wall portion 25a and a sidewall portion 25b, as illustrated in FIGS. 1, 4 and 5. The upper wall portion 25a is, for example, a plate-shaped body having an annular shape and extends along the horizontal direction. The inner peripheral edge of the upper wall portion 25a may face an end surface of the substrate W that is supported by the plurality of support pins 24. That is, the upper wall portion 25a may be disposed to surround the substrate W or the cleaning tool 100 that is supported by the plurality of support pins 24.

The upper surface of the inner peripheral portion of the upper wall portion 25a may include an inclined surface S1 inclined with respect to the horizontal direction. The entire upper surface of the inner peripheral portion of the upper wall portion 25a may be the inclined surface S1, or a portion of the upper surface of the inner peripheral portion of the upper wall portion 25a may be the inclined surface S1. The inclined surface S1 is inclined downward toward a radially inner side.

The lower surface of the inner peripheral portion of the upper wall portion 25a may include an inclined surface S2 inclined with respect to the horizontal direction. The entire lower surface of the inner peripheral portion of the upper wall portion 25a may be the inclined surface S2, or a portion of the lower surface of the inner peripheral portion of the upper wall portion 25a may be the inclined surface S2. The inclined surface S2 is inclined upward toward a radially inner side.

Due to the presence of the inclined surfaces S1 and S2, the inner peripheral portion of the upper wall portion 25a may have a tapered shape that narrows toward an inward side in the radial direction. Each of the inclined surfaces S1 and S2 may be a flat surface or a non-planar surface (e.g., a curved surface). In order to increase the fluidity of the cleaning liquid, a surface of the annular member 25 including the inclined surfaces S1 and S2 may include, for example, a plurality of irregularities by a dimple processing and/or an embossing, or may include grooves or protrusions extending in the radial direction. Alternatively, for the purpose of increasing the fluidity of the cleaning liquid, a surface treatment may be performed or a film may be formed on the surface of the annular member 25 including the inclined surfaces S1 and S2.

The sidewall portion 25b may have a cylindrical shape, for example. An upper end of the sidewall portion 25b may be integrally connected to an outer peripheral portion of the upper wall portion 25a. The sidewall portion 25b may have a tapered shape that narrows toward a downward direction.

As illustrated in FIG. 1, the lift unit 30 includes a shaft member 31, a plurality of support pins 32, and a drive mechanism 33. The shaft member 31 is a hollow tubular member extending in the vertical direction. The shaft member 31 is configured to be rotatable around the central axis Ax and to be lifted in the vertical direction. The shaft member 31 is inserted into and passed through the rotating shaft 21.

The plurality of support pins 32 are installed on the shaft member 31 to protrude upward from an upper end of the shaft member 31. The plurality of support pins 32 are configured to support the substrate W by the tips thereof contacting the lower surface Wa of the substrate W. The plurality of support pins 32 are configured to support the cleaning tool 100 by the tips thereof contacting the lower surface 101 of the cleaning tool 100. The plurality of support pins 32 may have, for example, a cylindrical shape or a conical shape. The plurality of support pins 32 may be disposed at approximately equal intervals to form a circular shape as a whole when viewed from above.

The drive mechanism 33 is connected to the shaft member 31. The drive mechanism 33 is configured to be operated to lift the shaft member 31 based on an operation signal from the controller Ctr. As the drive mechanism 33 lifts the shaft member 31, the shaft member 31 may be moved up and down between an upward position (not illustrated) in which the plurality of support pins 32 are positioned above the plurality of support pins 24 and a downward position (see, e.g., FIG. 1) in which the plurality of support pins 32 are positioned below the plurality of support pins 24. The drive mechanism 33 may be a power source such as a linear actuator.

The cover portion 40 has an annular shape and is installed to surround the outer peripheral portions of the annular member 25 and the support plate 23. The cover portion 40 serves as a liquid collection container that receives a processing liquid (e.g., the chemical liquid L1 and cleaning liquid L2 to be described below may be collectively referred to as a "processing liquid") supplied to the substrate W or the cleaning tool 100 and removed from the substrate W or the cleaning tool 100.

The cover portion 40 may include an upper wall portion 41, a sidewall portion 42, and a bottom wall portion 43, as illustrated in FIGS. 1, 4 and 5. The upper wall portion 41 is, for example, a plate-shaped body having an annular shape and extending along the horizontal direction. When viewed from above, the upper wall portion 41 at least partially overlaps the inclined surface S1, but does not overlap the substrate W or the cleaning tool 100 in a state of being supported by the plurality of support pins 24.

The sidewall portion 42 may have a cylindrical shape, for example. An upper end of the sidewall portion 42 may be integrally connected to an outer peripheral portion of the upper wall portion 41. The lower end of the sidewall portion 42 may be integrally connected to an outer peripheral portion of the bottom wall portion 43. The bottom wall portion 43 may be inclined upward toward an inward side in the radial direction. A through hole H is formed in a bottom portion of the bottom wall portion 43. The through hole H serves as a drainage flow path for discharging the cleaning liquid collected in the cover portion 40 to the outside of the substrate cleaning apparatus 1.

As illustrated in FIG. 1, the supply unit 50 is configured to supply the processing liquid to the lower surface Wa of the substrate W or the lower surface 101 of the cleaning tool 100 through the interior of the shaft member 31. That is, the shaft member 31 serves as a nozzle for supplying the processing liquid to the lower surface Wa of the substrate W or the lower surface 101 of the cleaning tool 100. The supply unit 50 includes liquid sources 51A and 51B, pumps 52A and 52B, valves 53A and 53B, and pipes 54A and 54B.

The liquid source 51A serves as a source of the chemical liquid L1. The chemical liquid L1 may include, for example, an alkaline or acidic chemical liquid for removing an unnecessary film such as SiN attached to the lower surface Wa of the substrate W. The alkaline chemical liquid may include, for example, an SC-1 solution (e.g., a mixture of ammonia, hydrogen peroxide and pure water). The acidic chemical liquid may include, for example, an SC-2 solution (e.g., a mixture of hydrochloric acid, hydrogen peroxide solution, and pure water), a SPM (e.g., a mixture of sulfuric acid and hydrogen peroxide solution), an HF/HNO₃ solution (a mixture of hydrofluoric acid and nitric acid).

The pump 52A is configured to be operated to draw in the chemical liquid L1 from the liquid source 51A and send the chemical liquid L1 to the shaft member 31 through the valve 53A and the pipe 54A, based on an operation signal from the controller Ctr. The valve 53A is configured to be operated to open and close the pipe 54A before and after the valve 53A, based on an operation signal from the controller Ctr. The pipe 54A connects the liquid source 51A, the pump 52A, and the valve 53A in an order from the upstream side.

The liquid source 51B serves as a supply source of the cleaning liquid L2. The cleaning liquid L2 may be, for example, a rinse liquid for washing away the foreign substances (e.g., particles and chemical residues). The cleaning liquid L2 may include, for example, pure water (deionized water, DIW), ozone water, carbonated water (CO₂ water), ammonia water, and the like.

The pump 52B is configured to be operated to draw in the cleaning liquid L2 from the liquid source 51B, and send the cleaning liquid L2 to the shaft member 31 through the valve 53B and the pipes 54A and 54B based on an operation signal from the controller Ctr. The valve 53B is configured to be operated to open and close the pipe 54B before and after the valve 53B based on an operation signal from the controller Ctr. The pipe 54B connects the liquid source 51B, the pump 52B, and the valve 53B in order from the upstream side. The downstream end of the pipe 54B is connected to the pipe 54A between the valve 53A and the shaft member 31.

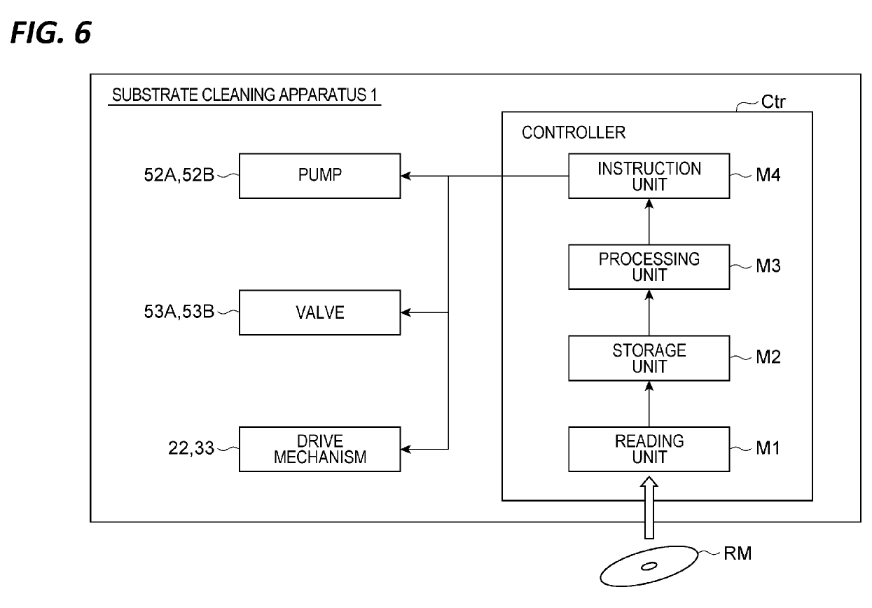

As illustrated in FIG. 6, the controller Ctr includes, as functional modules, a reading unit M1, a storage unit M2, a processing unit M3, and an instruction unit M4. These functional modules refer to a plurality of modules merely divided by functions of the controller Ctr for convenience, and do not necessarily mean that the hardware forming the controller Ctr is divided into these modules. Each functional module is not limited to a module implemented by the execution of the program, but may be implemented by a dedicated electrical circuit (e.g., a logical circuit) or an Application Specific Integrated Circuit (ASIC) in which the dedicated electrical circuit is integrated.

The reading unit M1 is configured to read a program from a computer-readable recording medium RM (e.g., a device). The recording medium RM records a program for operating each part of the substrate cleaning apparatus 1 (e.g., the drive mechanisms 22 and 33, the pumps 52A and 52B, and the valves 53A and 53B). As the recording medium RM, for example, a semiconductor memory, an optical recording disk, a magnetic recording disk, or a magneto-optical recording disk may be used. The recording medium RM may be embedded in the substrate cleaning apparatus 1 or may be separate from the substrate cleaning apparatus 1.

The storage unit M2 is configured to store various data. The storage unit M2 may store, for example, the program read from the recording medium RM in the reading unit M1 and setting data input from the operator through an external input device (not illustrated).

The processing unit M3 is configured to process various data. The processing unit M3 may be configured to generate an operation signal for operating each part of the substrate cleaning apparatus 1 based on various data stored in the storage unit M2, for example.

The instruction unit M4 is configured to transmit the operation signal generated in the processing unit M3 to each part of the substrate cleaning apparatus 1.

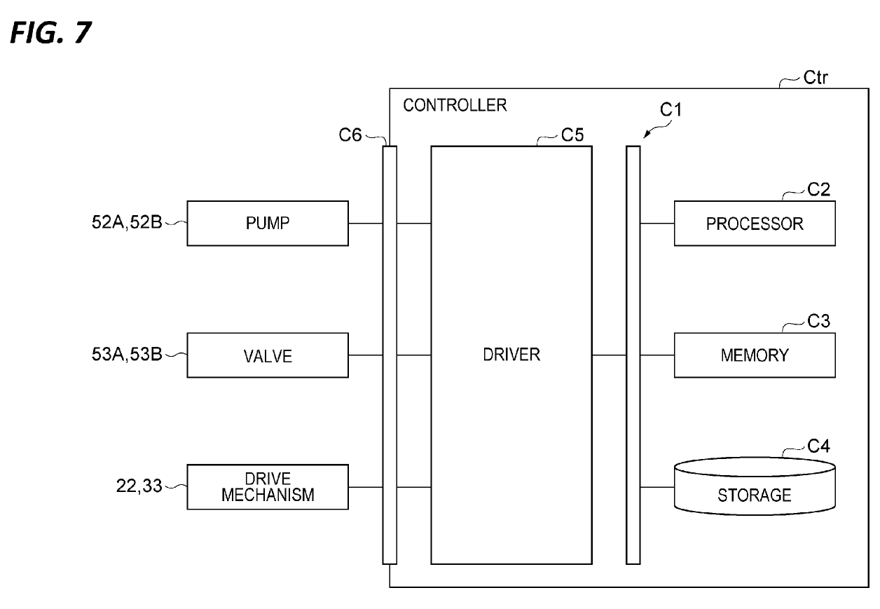

The hardware of the controller Ctr may be configured by, for example, one or a plurality of computers for control. The controller Ctr may include, for example, a circuit C1 illustrated in FIG. 7 as a configuration on hardware. The circuit C1 may include an electrical circuitry. The circuit C1 may include, for example, a processor C2, a memory C3 (e.g., a storage unit), a storage C4 (e.g., a storage unit), a driver C5, and an input/output port C6. The processor C2 configures each of the functional modules described above, by executing a program in cooperation with at least one of the memory C3 and the storage C4 and executing input/output of a signal through the input/output port C6. The memory C3 and the storage C4 serve as the storage unit M2. The driver C5 is a circuit that drives each part of the substrate cleaning apparatus 1. The input/output port C6 performs inputting and outputting signals between the driver C5 and each part of the substrate cleaning apparatus 1.

The substrate cleaning apparatus 1 may include one controller Ctr or include a controller group (e.g., control unit) including a plurality of controllers Ctr. In the latter case, each of the functional modules described above may be implemented by one controller Ctr or by a combination of two or more controllers Ctr. When the controller Ctr includes a plurality of computers (e.g., circuits C1), each of the functional modules described above may be implemented by one computer (circuit C1), or may be implemented by a combination of two or more computers (circuits C1). The controller Ctr may include a plurality of processors C2. In this case, each of the functional modules described above may be implemented by one processor C2, or may be implemented by a combination of two or more processors C2.

### Cleaning process

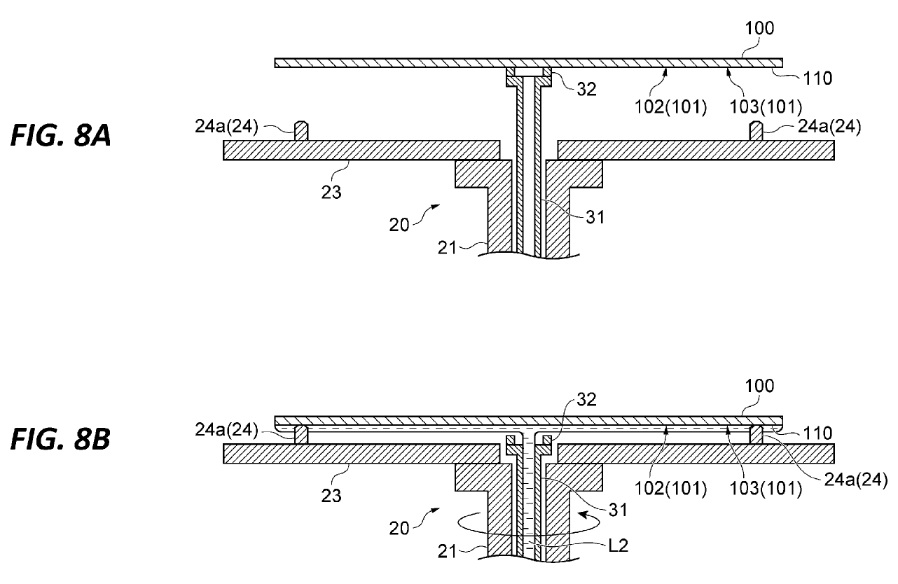

Referring to FIGS. 8 to 12, a cleaning process of the plurality of support pins 24 using the cleaning tool 100 in the substrate cleaning apparatus 1 will be described.

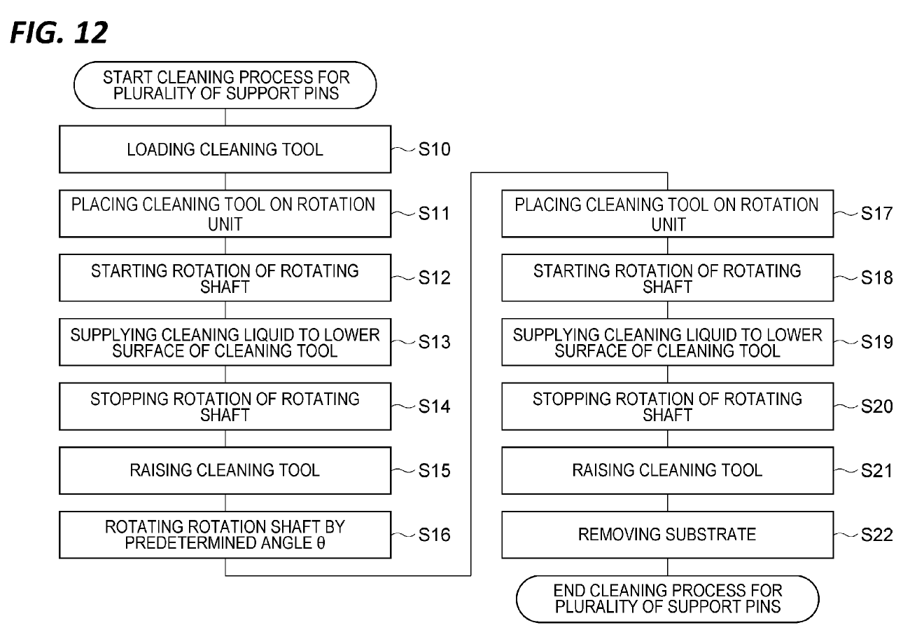

First, the cleaning tool 100 is loaded into the housing 10 by a transport mechanism (not illustrated) (see, e.g., step S10 of FIG. 12). At this time, the controller Ctr controls the drive mechanism 33 to place the shaft member 31 in a rising position. The cleaning tool 100 loaded into the housing 10 through the load/unload port 12 is delivered from the transport mechanism to the support pins 32. As a result, the cleaning tool 100 is disposed on the support pins 32 (e.g., the lift unit 30) so that the central region 102 of the lower surface 101 of the cleaning tool 100 comes into contact with the support pins 32 (see, e.g., FIG. 8A).

Subsequently, the controller Ctr controls the drive mechanism 33 to lower the shaft member 31 to a lowering position. In the process of lowering the shaft member 31, the cleaning tool 100 is delivered from the support pins 32 to the support pins 24. As a result, the cleaning tool 100 is disposed on the support pins 24 (the rotation unit 20) so that some support pins 24a of the plurality of support pins 24 come into contact with the corresponding protrusions 110 (see, e.g., FIG. 8B and step S11 of FIG. 12).

Subsequently, the controller Ctr controls the drive mechanism 22 to rotate the rotating shaft 21 at a predetermined rotational speed (see, e.g., FIG. 8B and step S12 of FIG. 12). At this time, the support plate 23 and the annular member 25 are rotated by the rotating shaft 21, and the cleaning tool 100 placed on the support pins 24 is also rotated.

Subsequently, the controller Ctr controls the supply unit 50 to supply the cleaning liquid L2 toward the central region 102 of the lower surface 101 of the rotating cleaning tool 100 through the shaft member 31 (see, e.g., FIG. 8B and step S13 of FIG. 12). As a result, as illustrated in FIG. 8B, the cleaning liquid L2 flows under centrifugal force along the lower surface 101 toward the outer peripheral edge of the lower surface 101 of the cleaning tool 100 and then is removed outward from the outer peripheral edge of the lower surface 101 of the cleaning tool 100.

At this time, the cleaning liquid L2 enters the recesses 120 and flows. In a state where the lower surface 101 of the cleaning tool 100 is supported by the rotation unit 20, the other support pins 24b of the plurality of support pins 24 are spaced apart from the lower surface 101 (the recesses 120) such that the tip portions of the support pins 24b are cleaned by the cleaning liquid L2 flowing into the recesses 120.

The cleaning liquid L2 removed from the lower surface 101 of the cleaning tool 100 flows between the annular member 25 and the cover 40, cleaning an outer surface of the upper wall portion 25a including the inclined surface S1 and an inner peripheral surface of the cover 40. The cleaning liquid L2 removed from the lower surface 101 of the cleaning tool 100 flows between the annular member 25 and the outer peripheral portion of the support plate 23, cleaning an inner surface of the upper wall portion 25a including the inclined surface S2. Then, the cleaning liquid L2 is collected in the cover 40 and discharged to the outside of the substrate cleaning apparatus 1 through the through hole H. After a predetermined period of time, the controller Ctr controls the supply unit 50 to stop the supply of the cleaning liquid L2.

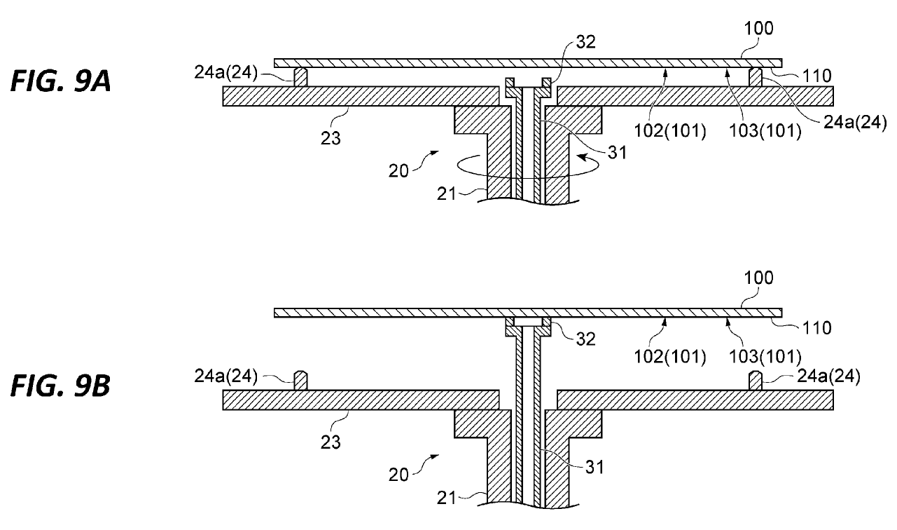

Subsequently, the controller Ctr controls the drive mechanism 22 to continue the rotation of the rotating shaft 21 for a predetermined period of time from the time point at which the supply of the cleaning liquid L2 is stopped and then stops the rotation of the rotating shaft 21 (see, e.g., FIG. 9A and step S14 of FIG. 12). As a result, the cleaning tool 100 is rotated until the rotation of the rotating shaft 21 is stopped such that the cleaning liquid L2 attached to the lower surface 101 of the cleaning tool 100 is dried. When the rotation of the rotating shaft 21 is stopped, the rotating shaft 21 may be stopped so that the rotation position around the central axis Ax of the rotating shaft 21 is a predetermined origin position (e.g., a position where the rotation angle of the rotating shaft 21 is 0°).

Subsequently, the controller Ctr controls the drive mechanism 33 to lift the shaft member 31 to the rising position. While the shaft member 31 is rising, the cleaning tool 100 is transferred from the support pins 24 to the support pins 32, and the cleaning tool 100 also rises (see e.g., FIG. 9B and step S15 of FIG. 12). As a result, the cleaning tool 100 is disposed on the support pins 32 so that the central region 102 of the lower surface 101 of the cleaning tool 100 comes into contact with the support pins 32.

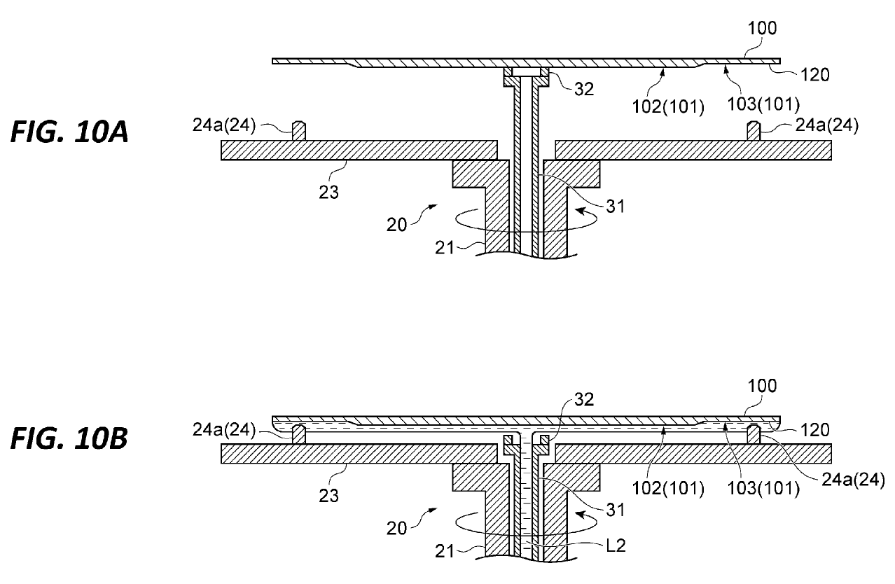

Subsequently, the controller Ctr controls the drive mechanism 22 to rotate the rotating shaft 21 by a predetermined angle θ (see e.g., FIG. 10A and step S16 of FIG. 12). In this case, the support plate 23 and the annular member 25 are rotated by the rotating shaft 21. When there are twelve support pins 24 disposed on the support plate 23 at approximately 30° intervals, the angle θ may be, for example, approximately 30°, or may be a multiple of 30°. As a result, some support pins 24b of the plurality of support pins 24 face the protrusions 110 of the cleaning tool 100 before the rotation by the angle θ respectively, but then face the recesses 120 of the cleaning tool 100 after the rotation by the angle θ. Meanwhile, the other support pins 24b of the plurality of support pins 24 face the recesses 120 of the cleaning tool 100 before the rotation by the angle θ respectively, but then face the protrusions 110 of the cleaning tool 100 after the rotation by the angle θ.

Subsequently, the controller Ctr controls the drive mechanism 33 to lower the shaft member 31 to the lowering position. In the process of lowering the shaft member 31, the cleaning tool 100 is delivered from the support pins 32 to the support pins 24. As a result, the cleaning tool 100 is disposed on the support pins 24 (e.g., the rotation unit 20) so that the other support pins 24b of the plurality of support pins 24 come into contact with the corresponding protrusions 110 (see, e.g., FIG. 10B and step S17 of FIG. 12).

Subsequently, the controller Ctr controls the drive mechanism 22 to rotate the rotating shaft 21 at a predetermined rotational speed (see, e.g., FIG. 10B and step S18 of FIG. 12). At this time, the support plate 23 and the annular member 25 are rotated by the rotating shaft 21, and the cleaning tool 100 placed on the support pins 24 is also rotated.

Subsequently, the controller Ctr controls the supply unit 50 to supply the cleaning liquid L2 toward the central region 102 of the lower surface 101 of the rotating cleaning tool 100 through the shaft member 31 (see, e.g., FIG. 10B and step S19 of FIG. 12). As a result, as illustrated in FIG. 10B, the cleaning liquid L2 flows under centrifugal force along the lower surface 101 toward the outer peripheral edge of the lower surface 101 of the cleaning tool 100 and then is removed outward from the outer peripheral edge of the lower surface 101 of the cleaning tool 100.

At this time, the cleaning liquid L2 enters the recesses 120 and flows. In a state where the lower surface 101 of the cleaning tool 100 is supported by the rotation unit 20, some support pins 24a of the plurality of support pins 24 are spaced apart from the lower surface 101 (e.g., the recesses 120) such that the tip portions of the support pins 24a are cleaned by the cleaning liquid L2 flowing into the recesses 120.

The cleaning liquid L2 removed from the lower surface 101 of the cleaning tool 100 flows between the annular member 25 and the cover 40, cleaning an outer surface of the upper wall portion 25a including the inclined surface S1 and an inner peripheral surface of the cover 40. The cleaning liquid L2 removed from the lower surface 101 of the cleaning tool 100 flows between the annular member 25 and the outer peripheral portion of the support plate 23, cleaning an inner surface of the upper wall portion 25a including the inclined surface S2. Then, the cleaning liquid L2 is collected in the cover 40 and discharged to the outside of the substrate cleaning apparatus 1 through the through hole H. After a predetermined period of time, the controller Ctr controls the supply unit 50 to stop the supply of the cleaning liquid L2.

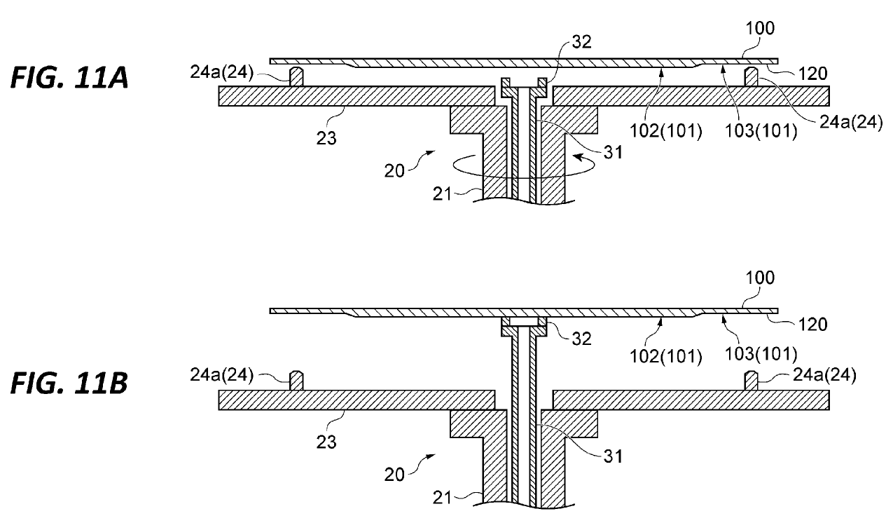

Subsequently, the controller Ctr controls the drive mechanism 22 to continue the rotation of the rotating shaft 21 for a predetermined period of time from the time point at which the supply of the cleaning liquid L2 is stopped and then stops the rotation of the rotating shaft 21 (see, e.g., FIG. 11A and step S20 of FIG. 12). As a result, the cleaning tool 100 is rotated until the rotation of the rotating shaft 21 is stopped such that the cleaning liquid L2 attached to the lower surface 101 of the cleaning tool 100 is dried.

Subsequently, the controller Ctr controls the drive mechanism 33 to lift the shaft member 31 to the rising position. While the shaft member 31 is rising, the cleaning tool 100 is transferred from the support pins 24 to the support pins 32, and the cleaning tool 100 also rises (see, e.g., FIG. 11B and step S21 of FIG. 12). As a result, the cleaning tool 100 is disposed on the support pins 32 so that the central region 102 of the lower surface 101 of the cleaning tool 100 comes into contact with the support pins 32.

Subsequently, a transport mechanism (not illustrated) receives the cleaning tool 100 from the support pins 32 and unloads the cleaning tool 100 out of the housing 10 (see, e.g., step S22 of FIG. 12). As described above, the cleaning process of the support pins 24 is completed.

### Operations

According to the examples described above, in the state where the lower surface 101 of the cleaning tool 100 is supported by the plurality of support pins 24, in the recesses 120, the other support pins 24b of the plurality of support pins 24 are spaced apart from the lower surface 101 of the cleaning tool 100. As a result, when the cleaning liquid L2 is supplied to the lower surface 101 of the cleaning tool 100, the cleaning liquid L2 flows into the recesses 120 such that the tip portions of the other support pins 24b are cleaned by the cleaning liquid L2. Therefore, it is possible to effectively clean the plurality of support pins 24.

According to the examples described above, as in the protrusions 110, the recesses 120 may extend in the radial direction of the cleaning tool 100 (e.g., the outer region 103). In this case, when the cleaning liquid L2 is supplied to the lower surface 101 of the cleaning tool 100, it is easy for the cleaning liquid L2 to flow from the center C toward the outer peripheral edge. Therefore, it is possible to effectively clean the annular member 25 and the cover 40 surrounding the cleaning tool 100 with the cleaning liquid L2.

According to the examples described above, the width (length in the circumferential direction) of the recesses 120 may gradually widen from the center C side toward the outer peripheral edge of the lower surface 101. In this case, when the cleaning liquid L2 is supplied to the lower surface 101 of the cleaning tool 100, it is easy for the cleaning liquid L2 to enter the recesses 120 and then spread widely in the recesses 120. Therefore, it is easy for the cleaning liquid L2 to reach the entire peripheral portion of the tip portions of the other support pins 24b. Therefore, it is possible to clean the plurality of support pins 24 more effectively.

According to the examples described above, the plurality of recesses 120 may extend radially. In this case, when the cleaning liquid L2 is supplied to the lower surface 101 of the cleaning tool 100, it is easy for the cleaning liquid L2 to flow from the center C toward the entire outer peripheral edge. Therefore, it is possible to clean the annular member 25 and the cover 40 surrounding the cleaning tool 100 with the cleaning liquid L2 more effectively.

According to the examples described above, the length d of the recesses 120 in the radial direction may be longer than the straight-line distance from the center C to the peripheral edge portion 121 of the recesses 120 in the radial direction. When the cleaning liquid L2 is supplied to the lower surface 101 of the cleaning tool 100, it is easy for the cleaning liquid L2 to enter the recesses 120 and then spread widely in the recesses 120. Therefore, it is easy for the cleaning liquid L2 to reach the entire peripheral portion of the tip portions of the other support pins 24b. Therefore, it is possible to clean the plurality of support pins 24 more effectively.

According to the examples described above, the peripheral edge portion 121 of the recesses 120 may be inclined so as to widen toward the outside of the recesses 120. In this case, after the cleaning liquid L2 is supplied to the lower surface 101 of the cleaning tool 100, the cleaning liquid L2 is unlikely to scatter when entering the recesses 120. Therefore, the cleaning liquid L2 flows smoothly in the recesses 120, making it easier for the cleaning liquid L2 to wash off the tip portions of the other support pins 24b. Therefore, it is possible to clean the plurality of support pins 24 more effectively.

According to the examples described above, the recesses 120 may be recessed deeper than the central region 102, and the protrusions 110 may be substantially co-planar with the central region 102. In this case, when the cleaning liquid L2 is supplied to the central region 102 of the cleaning tool 100, the flow of the cleaning liquid L2 from the central region 102 is unlikely to be disturbed before reaching the outer peripheral edge. Therefore, it is easy for the cleaning liquid L2 to be widely spread throughout the lower surface 101 of the cleaning tool 100. Therefore, it is possible to clean the annular member 25 and the cover portion 40 surrounding the cleaning tool 100 with the cleaning liquid L2 more effectively.

According to the examples described above, the cleaning liquid L2 is supplied to the central region 102 of the lower surface 101 of the cleaning tool 100. In this case, it is easy for the cleaning liquid L2 to flow from the center C toward the entire outer peripheral edge. Therefore, when the lower surface 101 of the cleaning tool 100 is supported by the plurality of support pins 24, it is possible to clean the annular member 25 and the cover portion 40 surrounding the cleaning tool 100 with the cleaning liquid L2 more effectively.

According to the examples described above, the recesses 120 are recessed deeper than the central region 102, the protrusions 110 is approximately co-planar with the central region 102, and the cleaning liquid L2 is supplied to the central region 102 of the lower surface 101 of the cleaning tool 100. In this case, when the cleaning liquid L2 flows from the center C toward the entire outer peripheral edge, in the outer region 103, since the protrusions 110 is approximately co-planar with the central region 102, the cleaning liquid L2 flows smoothly from the central region 102 to the protrusions 110. In addition, since the recesses 120 are recessed deeper than the central region 102 and the protrusions 110, the cleaning liquid L2 flows smoothly from the central region 102 to the recesses 120. Therefore, it is easier for the cleaning liquid L2 to flow further from the center C toward the entire outer peripheral edge. Therefore, it is possible to clean the annular member 25 and the cover 40 surrounding the cleaning tool 100 with the cleaning liquid L2 more effectively.

According to the examples described above, after the other support pins 24b of the plurality of support pins 24 are cleaned by the cleaning liquid L2, the relative positions of the plurality of support pins 24 with respect to the cleaning tool 100 are changed with the cleaning tool 100 being lifted. Therefore, when the cleaning liquid L2 is supplied to the lower surface 101 of the cleaning tool 100 after the change of the relative positions, the cleaning liquid L2 flows into the recesses 120, and the tip portions of some support pins 24a of the support pins 24 are cleaned by the cleaning liquid L2. In this way, by shifting the cleaning tool 100, the tip portions of all of the plurality of support pins 24 are cleaned by the cleaning liquid L2. Therefore, it is possible to clean the plurality of support pins 24 more effectively.

### Modification

It should be understood that certain aspects in this description are illustrative and not intended to be limiting in any respect. Various omissions, substitutions, modifications, etc. may be made to the examples described above without departing from the scope and spirit of the claims.

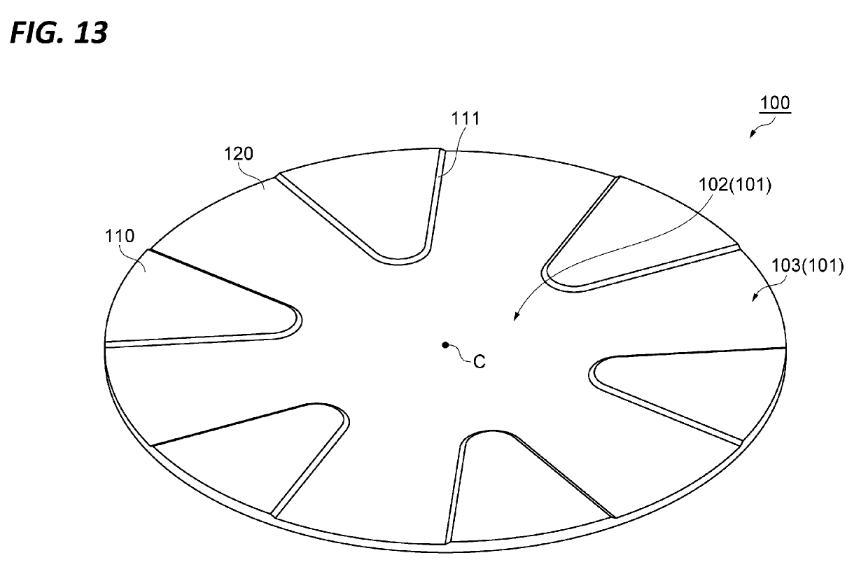

The surface of the protrusions 110 may protrude farther than the surface of the central region 102, as illustrated in FIG. 13. As illustrated in FIG. 13, the protrusions 110 may extend in the radial direction of the cleaning tool 100 (e.g., the outer region 103) (e.g., in this description, simply referred to as the "radial direction" in some cases). In other words, the protrusions 110 may extend in the radial direction from the center C side toward an outer peripheral edge of the lower surface 101. As illustrated in FIG. 13, when the plurality of protrusions 110 are formed in the outer region 103, the plurality of protrusions 110 may extend radially.

The width (e.g., the length in the circumferential direction) of the protrusions 110 may gradually widen from the center C side toward the outer peripheral edge of the lower surface 101. The protrusions 110 may have a fan shape or a triangular shape.

The length of the protrusions 110 in the radial direction may be longer than the straight-line distance from the center C in the radial direction to a peripheral edge portion 111 of the protrusions 110. When the peripheral edge portion 111 of the protrusions 110 extends from the boundary between the central region 102 and the outer region 103, the length of the protrusions 110 in the radial direction may be longer than the radius of the central region 102.

As illustrated in FIG. 13, the peripheral edge portion 111 of the protrusions 110 may be inclined to widen outward the protrusions 110. That is, the peripheral edge portion 111 may form an inclined surface that gradually decreases in height toward an outward side of the protrusions 110.

The surface of the recesses 120 may be substantially co-planar with the surface of the central region 102, as illustrated in FIG. 13. As illustrated in FIG. 13, the recesses 120 may extend in the radial direction of the cleaning tool 100 (the outer region 103).

In the examples described above, by rotating the support plate 23 by the angle θ, the cleaning tool 100 is shifted once and all support pins 24 are cleaned, but depending on the number of protrusions 110 and/or recesses 120, all support pins 24 may be cleaned while shifting the cleaning tool 100 multiple times.

### Other Examples

Example 1. An example of a cleaning tool for a substrate support member is a disc-shaped cleaning tool for cleaning a plurality of substrate support members, and the cleaning tool includes a lower surface including a central region including a center portion and an annular outer region extending outward from the central region, in which a cleaning liquid is supplied to the lower surface in a state where the lower surface is supported by the plurality of substrate support members, thereby cleaning the plurality of substrate support members. In a state where the lower surface is supported by the plurality of substrate support members, the outer region includes at least one protrusion at which some of the plurality of substrate support members are in contact with the lower surface, and at least one recess at which the other ones of the plurality of substrate support members are spaced apart from the lower surface. In this case, in the state where the lower surface is supported by the plurality of substrate support members, in the at least one recess, the other ones of the plurality of substrate support members are spaced apart from the lower surface of the cleaning tool. Therefore, when the cleaning liquid is supplied to the lower surface of the cleaning tool, the cleaning liquid flows into the at least one recess, and the tip portions of the other ones of the plurality of substrate support members are cleaned by the cleaning liquid. Therefore, it is possible to effectively clean the plurality of substrate support members.

Example 2. In the cleaning tool of Example 1, either the at least one recess or the at least one protrusion may extend in the radial direction from the center portion toward the outer peripheral edge of the lower surface. In this case, when the cleaning liquid is supplied to the lower surface of the cleaning tool, it is easy for the cleaning liquid to flow from the center portion toward the outer peripheral edge. Therefore, when there is an annular member surrounding the cleaning tool, the annular member may be effectively cleaned with the cleaning liquid.

Example 3. In the cleaning tool of Example 2, the at least one recess may have a width that gradually widens from the center portion toward the outer peripheral edge of the lower surface. In this case, when the cleaning liquid is supplied to the lower surface of the cleaning tool, it is easy for the cleaning liquid to enter the recess and then spread widely in the recess. Therefore, it is easy for the cleaning liquid to reach the entire peripheral portion of the tip portions of the other ones of the plurality of substrate support members. Therefore, the plurality of substrate support members may be more effectively cleaned.

Example 4. In the cleaning tool of any one of Examples 1 to 3, the at least one recess may include a plurality of recesses, and the plurality of recesses may extend radially. In this case, when the cleaning liquid is supplied to the lower surface of the cleaning tool, it is easy for the cleaning liquid to flow from the center portion toward the entire outer peripheral edge. Therefore, when there is an annular member surrounding the cleaning tool, the annular member may be more effectively cleaned with the cleaning liquid.

Example 5. In the cleaning tool of any one of Examples 1 to 4, the at least one recess may have a length in the radial direction may be longer than a straight-line distance from the center portion to the peripheral edge of the at least one recess in the radial direction. In this case, the same effect as the cleaning tool of Example 3 may be obtained.

Example 6. In the cleaning tool of any one of Examples 1 to 5, the peripheral edge of the at least one recess may be inclined to widen outward the recess. In this case, after the cleaning liquid is supplied to the lower surface of the cleaning tool, the cleaning liquid is unlikely to scatter when entering the at least one recess. Therefore, since the cleaning liquid flows smoothly in the at least one recess, it is easy for the cleaning liquid to wash off the tip portions of the other ones of the plurality of substrate support members. Therefore, the plurality of substrate support members may be more effectively cleaned.

Example 7. In the cleaning tool of any one of Examples 1 to 6, the at least one recess may be recessed relative to the central region, and the at least one protrusion may be substantially co-planar with the central region. In this case, when the cleaning liquid is supplied to the central region of the cleaning tool, the flow of the cleaning liquid is unlikely to be disturbed before reaching the outer peripheral edge from the central region. Therefore, it is easy for the cleaning liquid to spread widely throughout the lower surface. Therefore, when there is an annular member surrounding the cleaning tool, the annular member may be more effectively cleaned with the cleaning liquid.

Example 8. An example of the substrate processing apparatus includes a disc-shaped cleaning tool, a support including a plurality of substrate support members that supports lower surfaces of the substrate and the cleaning tool, a rotation unit that rotates the support, a supply unit that supplies the cleaning liquid to the lower surfaces of the substrate and the cleaning tool supported by the support, and a control unit. The lower surface of the cleaning tool includes a central region including a portion and an annular outer region extending outward from the central region. In a state where the lower surface of the cleaning tool is supported by the plurality of substrate support members, the outer region includes at least one protrusion at which some of the plurality of substrate support members are in contact with the lower surface of the cleaning tool, and at least one recess at which the other ones of the plurality of substrate support members are spaced apart from the lower surface of the cleaning tool. The control unit is configured to perform a first process of controlling the rotation unit to rotate the support in a state where the lower surface of the cleaning tool is supported by the plurality of substrate supports such that the at least one of the plurality of substrate supports is in contact with the at least one protrusion and the remaining ones of the plurality of substrate supports are spaced apart from the at least one recess, thereby rotating the cleaning tool, and a second process of controlling the supply unit to supply the cleaning liquid to the lower surface of the cleaning tool while rotating the cleaning tool in the first process. In this case, in the state where the lower surface of the cleaning tool is supported by the plurality of substrate support members, in the at least one recess, the other ones of the plurality of substrate support members are spaced apart from the lower surface of the cleaning tool. Therefore, when the cleaning liquid is supplied to the lower surface of the cleaning tool in the second process, the cleaning liquid flows into the at least one recess, and the tip portions of the other ones of the plurality of substrate support members are cleaned by the cleaning liquid. Therefore, the plurality of substrate support members may be effectively cleaned.

Example 9. In the apparatus of Example 8, after the second process, the control unit may be configured to further perform a third process of controlling the rotation unit to rotate the support such that the cleaning tool is dried.

Example 10. The apparatus of Example 8 further includes a lift unit that lifts the substrate, in which the control unit may be configured to further perform: after the second process, a fourth process of controlling the lift unit to lift the cleaning tool such that the cleaning tool is separated from the plurality of substrate support members; after the fourth process, a fifth process of controlling the rotation unit to rotate the support such that relative positions of the plurality of substrate support members are changed with respect to the cleaning tool; after the fifth process, a sixth process of controlling the lift unit to lower the cleaning tool such that the other ones of the plurality of substrate support members are in contact with the at least one protrusion and some of the plurality of substrate support members are spaced apart from at least one recess, thereby supporting the cleaning tool on the plurality of substrate support members; after the sixth process, a seventh process of controlling the rotation unit to rotate the support such that the cleaning tool is rotated; and an eighth process of controlling the supply unit to supply the cleaning liquid to the lower surface of the cleaning tool while rotating the cleaning tool in the seventh process. In this case, after the other ones of the plurality of substrate support members are cleaned by the cleaning liquid in the second process, in a state where the cleaning tool is lifted by the lift unit, the relative positions of the cleaning tool and the plurality of substrate support members are changed by the rotation unit. Therefore, when the cleaning liquid is supplied to the lower surface of the cleaning tool in the eighth process, the cleaning liquid flows into the at least one recess, and the tip portions of some of the plurality of substrate support members are cleaned by the cleaning liquid. In this way, by shifting the cleaning tool, the tip portions of all of the plurality of substrate support members are cleaned by the cleaning liquid. Therefore, the plurality of substrate support members may be more effectively cleaned.

Example 11. In the apparatus of any one of Examples 8 to 10, the second process may include controlling the supply unit to supply the cleaning liquid to the central region of the cleaning tool. In this case, it is easy for the cleaning liquid to flow from the portion toward the entire outer peripheral edge. Therefore, in the state where the lower surface of the cleaning tool is supported by the plurality of substrate support members, when there is an annular member surrounding the cleaning tool, the annular member may be more effectively cleaned with the cleaning liquid.

Example 12. In the apparatus of any one of Examples 8 to 11, either the at least one recess or the at least one protrusion may extend in a radial direction from the portion toward the outer peripheral edge of the lower surface. In this case, the same effect as the cleaning tool of Example 2 may be obtained.

Example 13. In the apparatus of Example 12, the at least one recess may have a width that gradually widens from the portion toward the outer peripheral edge of the lower surface. In this case, the same effect as the cleaning tool of Example 3 may be obtained.

Example 14. In the apparatus of any one of Examples 8 to 13, the at least one recess may include a plurality of recesses, and the plurality of recesses may extend radially. In this case, the same effect as the cleaning tool of Example 4 may be obtained.

Example 15. In the apparatus of any one of Examples 8 to 14, the at least one recess may have a length in the radial direction that is longer than a straight-line distance from the center portion to the peripheral edge portion of the at least one recess in the radial direction. In this case, the same effect as the cleaning tool of Example 3 may be obtained.

Example 16. In the apparatus of any one of Examples 8 to 15, the peripheral edge portion of the at least one recess may be inclined to widen outward the recess. In this case, the same effect as the cleaning tool of Example 6 may be obtained.

Example 17. In the apparatus of any one of Examples 8 to 16, the at least one recess may be recessed relative to the central region, and the at least one protrusion may be substantially co-planar with the central region. In this case, the same effect as the cleaning tool of Example 7 may be obtained.

Example 18. An example of a method for cleaning the substrate support member is a method for cleaning a plurality of substrate support members by a cleaning tool having a disc shape, in which the method may include: a first process of supporting a lower surface of the cleaning tool on a plurality of substrate support members, in which the lower surface of the cleaning tool includes a central region including a center portion and an annular outer region extending outward from the central region, the outer region includes at least one protrusion and at least one recess formed therein, and in a state where the lower surface of the cleaning tool is supported by the plurality of substrate support members, some of the plurality of substrate support members are in contact with the at least one protrusion, and the other ones of the plurality of substrate support members are spaced apart from the at least one recess; after the first process, a second process of rotating the cleaning tool; and a third process of supplying the cleaning liquid to the lower surface of the cleaning tool while rotating the cleaning tool in the first process. In this case, the same effect as the method of Example 8 may be obtained.

Example 19. The method of Example 18 may further include: after the third process, a fourth process of lifting the cleaning tool to separate the cleaning tool from the plurality of substrate support members; after the fourth process, a fifth process of rotating the cleaning tool by a predetermined angle; after the fifth process, a sixth process of lowering the cleaning tool such that the other ones of the plurality of substrate support members are in contact with the at least one protrusion and some of the plurality of substrate support members are spaced apart from at least one recess, thereby supporting the cleaning tool on the plurality of substrate support members; after the sixth process, a seventh process of rotating the cleaning tool; and an eighth process of supplying the cleaning liquid to the lower surface of the cleaning tool while rotating the cleaning tool in the seventh process. In this case, the same effect as the method of Example 10 may be obtained.

Example 20. In the method of Example 18 or 19, the third process may include supplying the cleaning liquid to the central region of the cleaning tool. In this case, the same effect as the method of Example 11 may be obtained.

With the cleaning tool for the substrate support member, and the substrate processing apparatus and the method for cleaning the substrate support member according to the present disclosure, it is possible to effectively clean the substrate support member.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A cleaning tool for cleaning a plurality of substrate supports, the cleaning tool comprising:
a lower surface including a central region including a center portion and an outer region extending outward from the central region,
wherein a cleaning liquid is supplied to the lower surface in a state where the lower surface is supported by at least one of the plurality of substrate supports, thereby cleaning the plurality of substrate supports,
wherein, in a state where the lower surface is supported by at least one of the plurality of substrate supports, the outer region includes at least one protrusion at which the at least one of the plurality of substrate supports is in contact with the lower surface, and at least one recess at which remaining ones of the plurality of substrate support members are spaced apart from the lower surface.

2. The cleaning tool according to claim 1, wherein either the at least one recess or the at least one protrusion extends in a radial direction from the center portion toward an outer peripheral edge of the lower surface.

3. The cleaning tool according to claim 2, wherein the at least one recess has a width that gradually widens from the center portion toward the outer peripheral edge of the lower surface.

4. The cleaning tool according to claim 1, wherein the at least one recess includes a plurality of recesses, and
the plurality of recesses extend radially.

5. The cleaning tool according to claim 1, wherein the at least one recess has a length in a radial direction that is longer than a straight-line distance from the center portion to a peripheral edge of the at least one recess in the radial direction.

6. The cleaning tool according to claim 5, wherein the peripheral edge of the at least one recess is inclined to widen outward the recess.

7. The cleaning tool according to claim 1, wherein the at least one recess is recessed relative to the central region, and the at least one protrusion is substantially co-planar with the central region.

8. A substrate processing apparatus comprising:
a cleaning tool having a disc shape;
a support unit including a plurality of substrate supports configured to support lower surfaces of the substrate and the cleaning tool;
a rotation unit including a driver configured to rotate the support;
a supply configured to supply a cleaning liquid to the lower surfaces of the substrate and the cleaning tool supported by the support unit; and
a controller,
wherein the lower surface of the cleaning tool includes a central region including a center portion and an outer region extending outward from the central region,
in a state where the lower surface of the cleaning tool is supported by the plurality of substrate supports, the outer region includes at least one protrusion at which at least one of the plurality of substrate supports are in contact with the lower surface of the cleaning tool, and at least one recess at which remaining ones of the plurality of substrate supports are spaced apart from the lower surface of the cleaning tool,
the control unit is configured to perform
a first process of controlling the rotation unit to rotate the support in a state where the lower surface of the cleaning tool is supported by the plurality of substrate supports such that the at least one of the plurality of substrate supports is in contact with the at least one protrusion and the remaining ones of the plurality of substrate supports are spaced apart from the at least one recess, thereby rotating the cleaning tool, and
a second process of controlling the supply to supply the cleaning liquid to the lower surface of the cleaning tool while rotating the cleaning tool in the first process.

9. The substrate processing apparatus according to claim 8, wherein the controller is further configured to perform, after the second process, a third process of controlling the rotation unit to rotate the support unit such that the cleaning tool is dried.

10. The substrate processing apparatus according to claim 8, further comprising:
a lift configured to lift the substrate,
wherein the controller is further configured to perform:
after the second process, a fourth process of controlling the lift to lift the cleaning tool such that the cleaning tool is separated from the plurality of substrate supports;
after the fourth process, a fifth process of controlling the rotation unit to rotate the support unit such that relative positions of the plurality of substrate supports are changed with respect to the cleaning tool;
after the fifth process, a sixth process of controlling the lift to lower the cleaning tool such that the remaining ones of the plurality of substrate supports are in contact with the at least one protrusion and the at least one of the plurality of substrate supports are spaced apart from at least one recess, thereby supporting the cleaning tool on the plurality of substrate supports;
after the sixth process, a seventh process of controlling the rotation unit to rotate the support such that the cleaning tool is rotated; and
an eighth process of controlling the supply to supply the cleaning liquid to the lower surface of the cleaning tool while rotating the cleaning tool in the seventh process.

11. The substrate processing apparatus according to claim 8, wherein the second process includes controlling the supply to supply the cleaning liquid to the central region of the cleaning tool.

12. The substrate processing apparatus according to claim 8, wherein either the at least one recess or the at least one protrusion extends in a radial direction from the center portion toward the outer peripheral edge of the lower surface.

13. The substrate processing apparatus according to claim 12, wherein the at least one recess has a width that gradually widens from the center portion toward the outer peripheral edge of the lower surface.

14. The substrate processing apparatus according to claim 8, wherein
the at least one recess includes a plurality of recesses, and
the plurality of recesses extend radially.

15. The substrate processing apparatus according to claim 8, wherein the at least one recess has a length in a radial direction that is longer than a straight-line distance from the center portion to a peripheral edge of the at least one recess in the radial direction.

16. The substrate processing apparatus according to claim 15, wherein the peripheral edge of the at least one recess is inclined to widen outward the recess.

17. The substrate processing apparatus according to claim 8, wherein the at least one recess is recessed relative to the central region, and the at least one protrusion is substantially co-planar with the central region.

18. A method for cleaning a plurality of substrate supports by a cleaning tool, the method comprising:
supporting a lower surface of the cleaning tool on a plurality of substrate supports, wherein the lower surface of the cleaning tool includes a central region including a center portion and an outer region extending outward from the central region, the outer region includes at least one protrusion and at least one recess formed therein, and in a state where the lower surface of the cleaning tool is supported by the plurality of substrate supports, at least one of the plurality of substrate supports is in contact with the at least one protrusion, and remaining ones of the plurality of substrate supports are spaced apart from the at least one recess;
after the supporting, first rotating the cleaning tool; and
supplying the cleaning liquid to the lower surface of the cleaning tool while rotating the cleaning tool in the first rotating.

19. The method according to claim 18, further comprising:
after the supplying, lifting the cleaning tool to separate the cleaning tool from the plurality of substrate supports;
after the lifting, second rotating the cleaning tool by a predetermined angle;
after the second rotating, lowering the cleaning tool such that the remaining ones of the plurality of substrate supports are in contact with the at least one protrusion and the at least one of the plurality of substrate supports are spaced apart from at least one recess, thereby supporting the cleaning tool on the plurality of substrate supports;
after the lowering, third rotating the cleaning tool; and
supplying the cleaning liquid to the lower surface of the cleaning tool while the cleaning tool in the third rotating.

20. The method according to claim 18, wherein the supplying includes supplying the cleaning liquid to the central region of the cleaning tool.
